(19) United States
(12) Patent Application Publication
(10) Pub. No.: US 2015/0221733 A1
(43) Pub. Date: Aug. 6, 2015

(54) TRENCH MOSFET WITH SELF-ALIGNED SOURCE AND CONTACT REGIONS USING THREE MASKS PROCESS

(71) Applicant: Force Mos Technology Co., Ltd., New Taipei City (TW)

(72) Inventor: FU-YUAN HSIEH, New Taipei City (TW)

(73) Assignee: Force Mos Technology Co., Ltd., New Taipei City (TW)

(21) Appl. No.: 14/170,784

(22) Filed: Feb. 3, 2014

(51) Int. Cl. H01L 29/423; H01L 29/78; H01L 21/306; H01L 21/225; H01L 29/06; H01L 21/265; H01L 29/66; H01L 29/40

(52) U.S. Cl. CPC H01L 29/4236; H01L 29/66666; H01L 29/7827; H01L 29/404; H01L 29/407; H01L 21/225; H01L 29/0696; H01L 29/66734; H01L 29/7811; H01L 29/7813; H01L 21/265; H01L 21/30604

(57) ABSTRACT

A trench MOSFET structure having self-aligned features for mask saving and on-resistance reduction is disclosed, wherein source regions are formed by performing source Ion Implantation through contact holes of a contact interlayer in the middle of adjacent terrace trenched gates, and further source diffusion. Both the contact holes and source regions are self-aligned to the terrace trenched gates.

### FIELD OF THE INVENTION

This invention relates generally to the cell configuration and fabrication process of trench metal-oxide-semiconductor-field-effect-transistor (MOSFET). More particularly, this invention relates to a novel and improved cell structure and improved process of fabricating a trench MOSFET with self-aligned source and contact regions using three masks process.

### BACKGROUND OF THE INVENTION

FIG. 1 shows an N-channel trench MOSFET 100 disclosed in U.S. Pat. No. 8,058,685 which has improved UIS (Unclamp inductance Switching) capability because that the n+source regions 101 are self-aligned to a contact mask (not shown) which is used to define both contact regions for trenched source-body contacts 102 and implantation regions for the n+ source regions 101, therefore, a source mask is saved as another advantage of the prior art.

There are two technological constrains encountered by the trench MOSFET 100 introduced above: high gate resistance Rg due to less poly-silicon 103 refilled within the gate trenches 104 when trench depth and width become shallower and narrower; and non-uniform distribution of avalanche current My and on-resistance Rds across wafer due to non-self-aligned source-body contact to gate trench. Both the constrains are explained as below:

To further reduce Qgd (gate charge between gate and drain) and Rds, trench width of the trench MOSFET is often narrow/shallow, which also meets the requirement of higher cell density. However, a high Rg is therefore introduced when refilling poly-silicon material within this narrow/shallow gate trench. Meanwhile, when forming a trenched gate contact 105 into the poly-silicon material, a shortage issue between gate and drain may occur as this narrow/shallow gate trench is easily to penetrate through.

Meanwhile, as the location of the n+ source regions 101 and the trenched source-body contacts 102 are dependent on the contact mask, a misalignment between the trenched source-body contact and the gate trench occurs easily when the contact mask is not etched in the place right between the two gate trenches, resulting in non-uniform distribution of UIS current or avalanche current tax across wafer, as well as the on-resistance Rds between drain and source.

Therefore, there is still a need in the art of the semiconductor device design and fabrication, particularly for trench MOSFET design and fabrication, to provide a novel cell structure, device configuration and fabrication process that would resolve these difficulties and design limitations.

### SUMMARY OF THE INVENTION

The present invention provides a trench MOSFET with self-aligned source and contact regions to gate trenches by employing terrace trenched gate structure, therefore, the location of source regions and trenched source-body contacts are defined by a source contact hole which is formed self-aligned to adjacent terrace trenched gates, resolving the problem of UIS instability when a contact mask is misaligned to trenched gates in prior arts. Meanwhile, as the poly-silicon within the gate trench is replaced by the terrace trenched gate, additional poly-silicon is provided over silicon mesa to further reduce gate resistance Rg. Furthermore, another advantage is brought which avoids the possible shortage issue between gate and drain due to greater depth of the terrace trenched gates.

Briefly, the invention features a trench MOSFET formed in an epitaxial layer of a first conductivity type and comprising a plurality of terrace trenched gates surrounded by source regions heavily doped with the first conductivity type in an active area encompassed in body regions of a second conductivity type above a drain region, wherein: the terrace trenched gates comprise poly-silicon material disposed in gate trenches and padded by a gate oxide layer, wherein the poly-silicon material has a top surface higher than a silicon mesa between two adjacent gate trenches; the source regions formed between trenched source-body contacts and adjacent gate trenches have a higher doping concentration and a greater junction depth near sidewalls of the trenched source-body contacts than near the adjacent gate trenches, wherein the trenched source-body contacts are self-aligned to adjacent terrace trenched gates.

According to another aspect of the present invention, a top portion of each the trenched source-body contact has a greater trench width than a bottom portion.

According to another aspect of the present invention, the trench MOSFET further comprises a gate contact area including a wider terrace trenched gate disposed in a wider gate trench, wherein the wider terrace trenched gate is connected to a gate metal layer through a trenched gate contact.

According to another aspect of the present invention, the trench MOSFET further comprises a termination area including multiple of floating trenched gates which are spaced apart from each other by the body regions having floating voltage, wherein the floating trenched gates also have similar terrace trenched gate structure as the terrace trenched gates in the active area.

The present invention also features a method for manufacturing the trench MOSFET according to the present invention, comprising: forming a plurality of terrace trenched gates in a plurality of gate trenches in an epitaxial layer of a first conductivity type, wherein the terrace trenched gates have a top surface higher than the epitaxial layer; forming a plurality of body regions of a second conductivity type extending between two adjacent of the gate trenches in the epitaxial layer; depositing a contact interlayer covering outer surface of the terrace trenched gates, forming a source contact hole at the middle of every two adjacent of the terrace trenched gates; etching the source contact hole to expose partial top surface of the epitaxial layer; carrying out ion implantation of the first conductivity type through the source contact hole to form source regions right below the source contact hole in the epitaxial layer; performing diffusion to extend the source regions to adjacent gate trenches.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a trench MOSFET of prior art.

FIG. 2 is a cross-sectional view of a preferred embodiment according to the present invention.

FIGS. 3A to 3K are cross-sectional views showing the forming steps of the preferred embodiment according to the present invention.

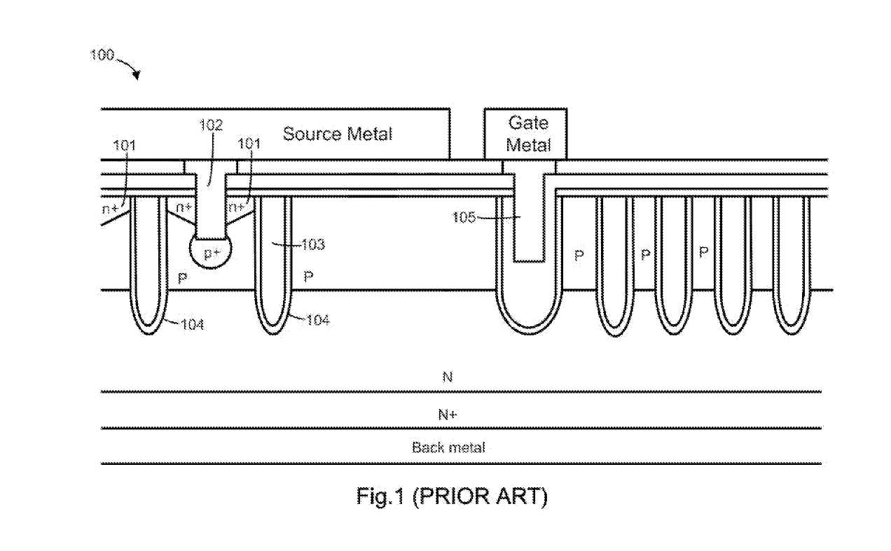

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be make without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

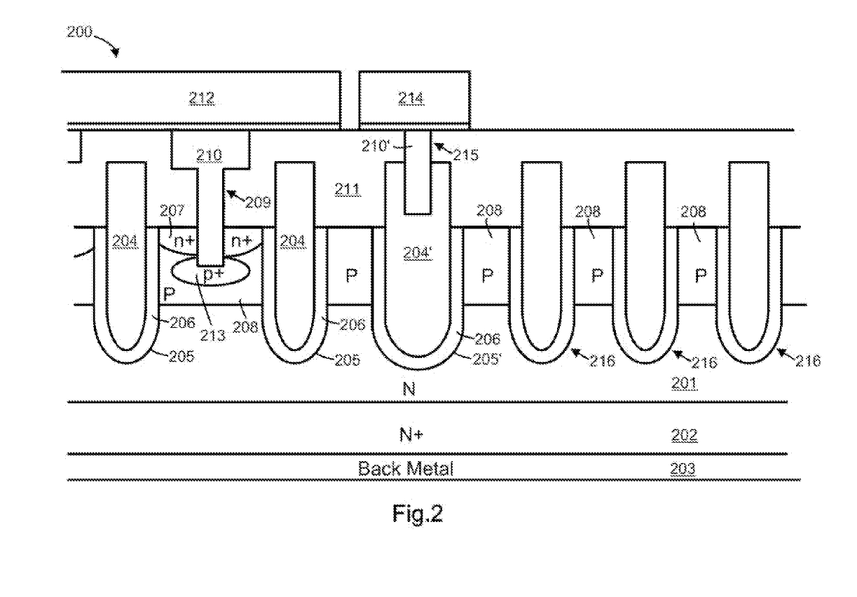

Please refer to FIG. 2 for a preferred embodiment of this invention wherein an N-channel trench MOSFET 200 is formed in an N epitaxial layer 201 onto an N+ substrate 202 with a back metal layer on rear side as drain metal 203 (the conductivity type here is not to be taken in a limiting sense, which means it also can be implemented to be a P-channel trench MOSFET formed in a P epitaxial layer onto a P+ substrate). The N-channel trench MOSFET 200 further comprises an active area including: a plurality of terrace trenched gates 204 formed in a plurality of gate trenches 205 and padded by a gate oxide layer 206 close to sidewalls of the gate trenches 205; a plurality of n+source regions 207 formed near top surface of the N epitaxial layer 201 and encompassed in a plurality of P body regions 208 which are extending between two adjacent of the gate trenches 205; a plurality of trenched source-body contacts 209 each filled with a contact metal plug 210 and formed right between every two adjacent of the gate trenches 205, penetrating through a contact interlayer 211, the n+ source regions 207 and extending into the P body regions 208, connecting the n+ source regions 207 and the P body regions 208 to a source metal layer 212. According to the present invention, the terrace trenched gates 204 have top surface higher than top surface of the n+ source regions 207, at the same time, the n+ source regions 207 have a higher doping concentration and a greater junction depth near sidewalls of the trenched source-body contacts 209 than near adjacent channel regions, more specific, the n+ source regions 207 have a Gaussian-distribution profile from the sidewalls of the trenched source-body contacts to the adjacent channel regions. Around bottom of each the trenched source-body contact 209, a p+ ohmic body contact region 213 is formed underneath the n+ source regions 207 to reduce the contact resistance between the P body regions 208 and the contact metal plug 210. The terrace trenched gates 204 further extend to a wider terrace trenched gate 204′ in a gate contact area which is formed in a wider gate trench 205′ and padded by the gate oxide layer 206, the wider terrace trenched gate 204′ is connected to a gate metal layer 214 through a trenched gate contact 215 filled with a contact metal plug 210′. The N-channel trench MOSFET 200 further comprises a termination area including multiple of trenched floating gates 216 which are spaced apart from each other by the P body regions 208 having a floating voltage.

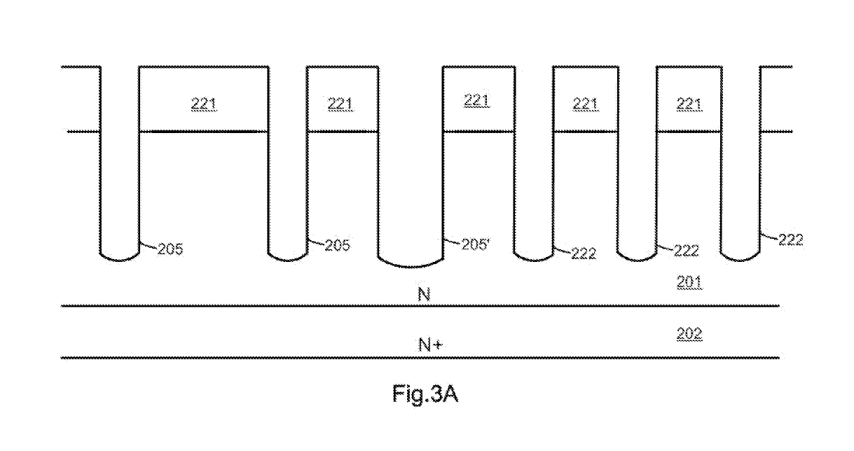

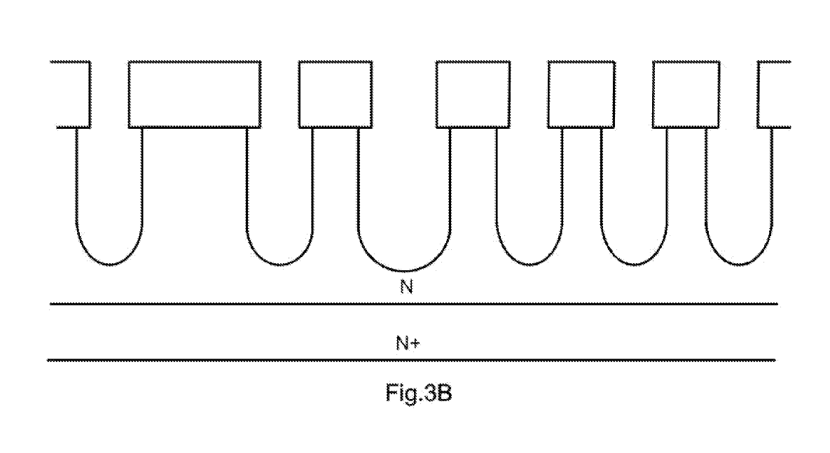

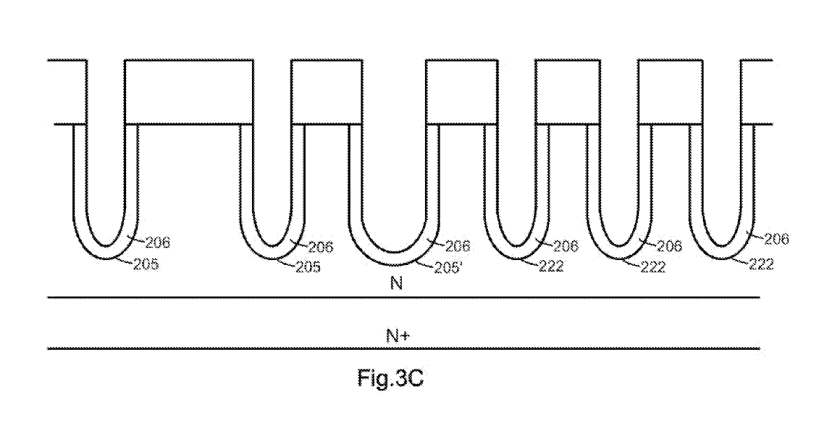

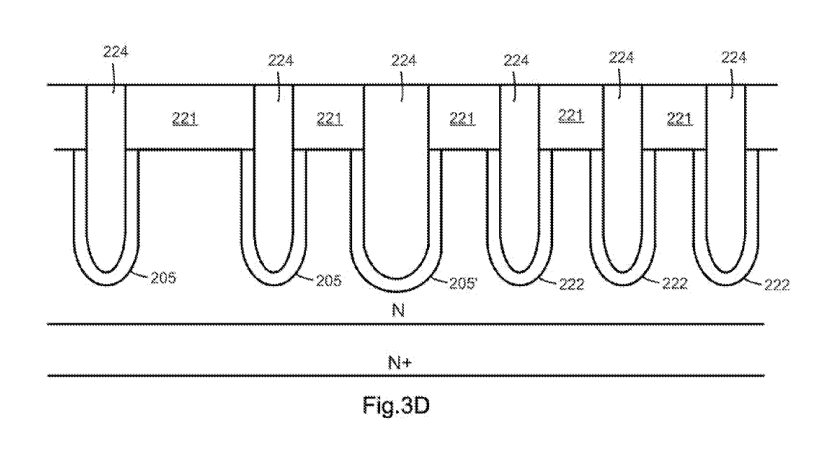

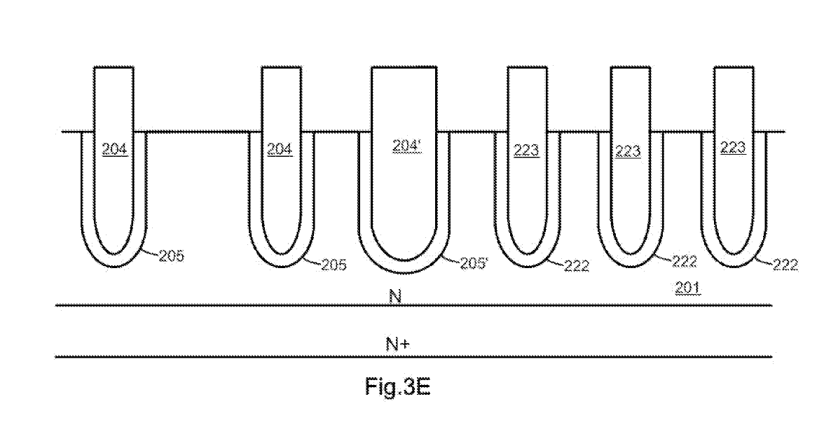

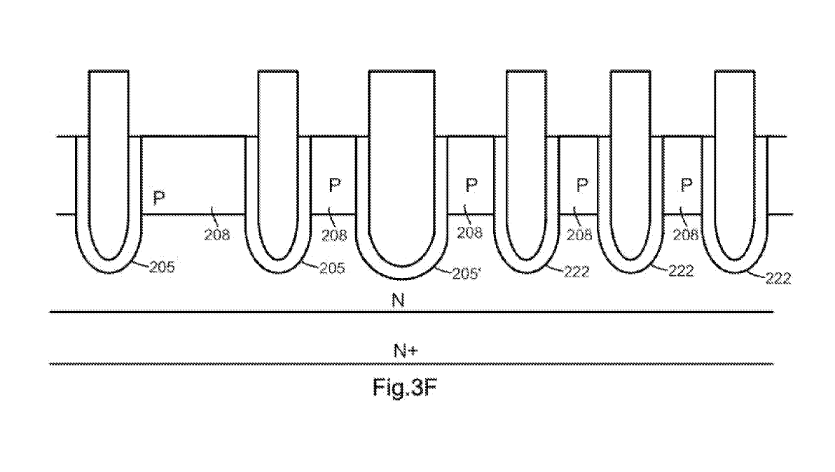

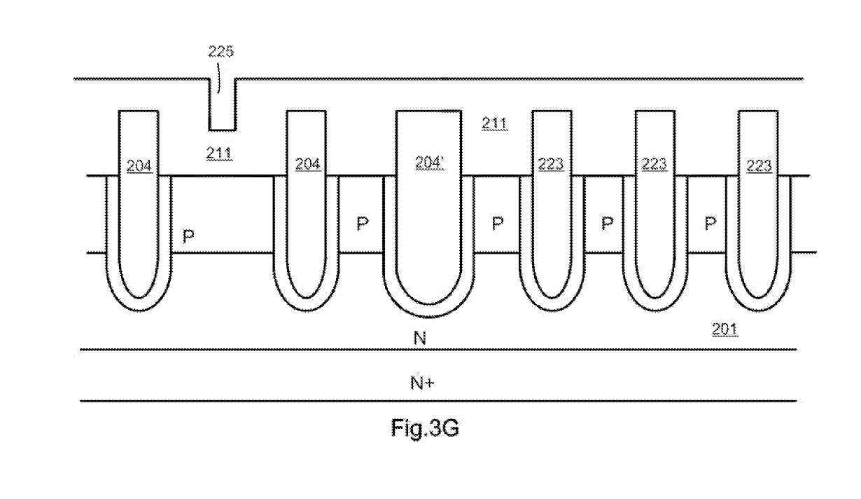

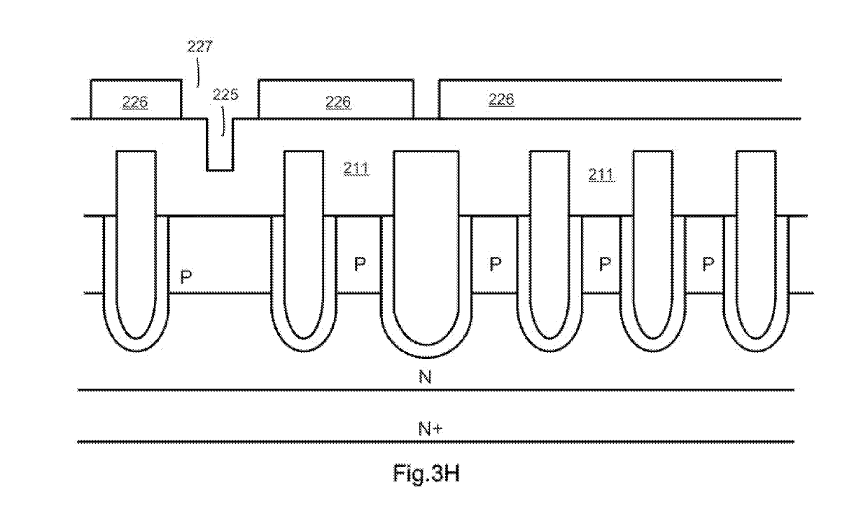

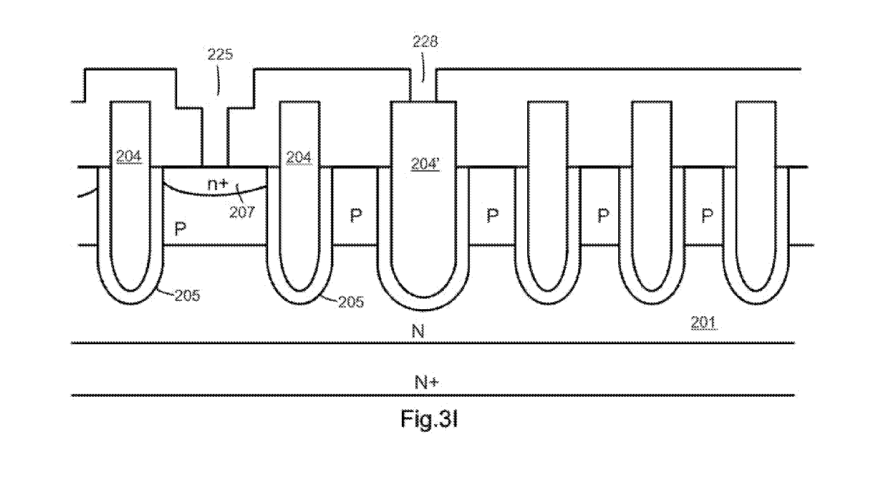

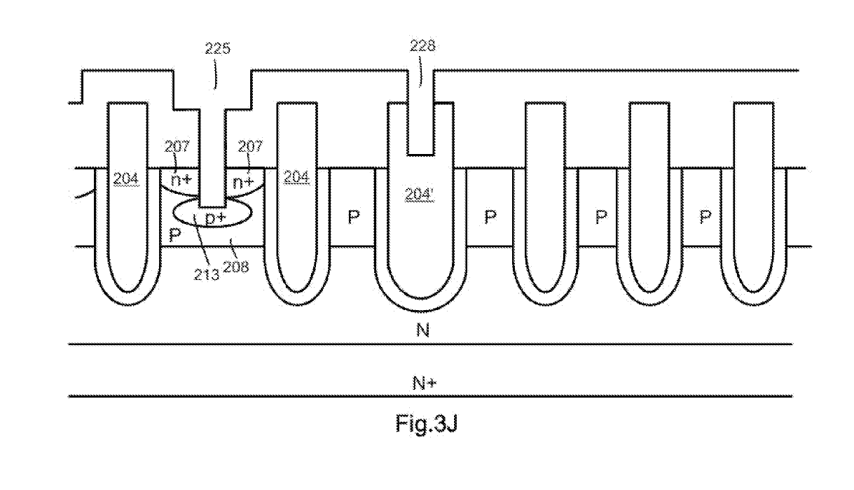

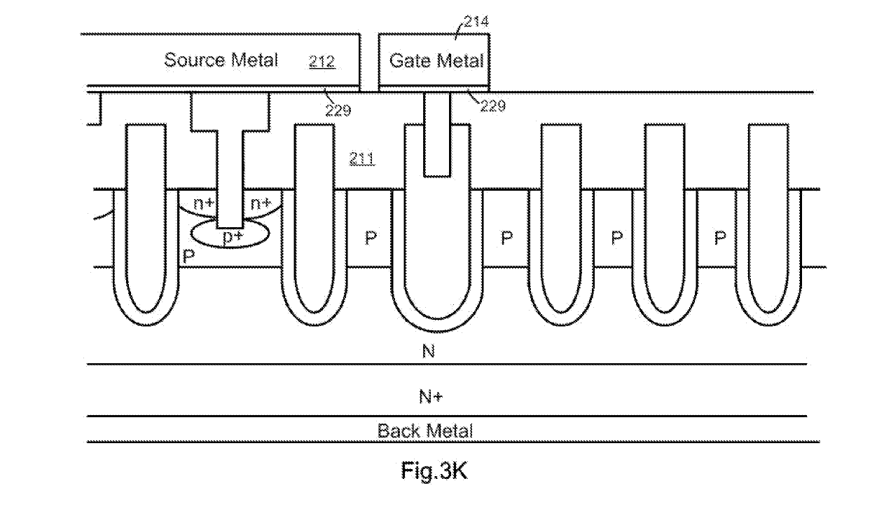

FIGS. 3A to 3K are cross-sectional views for showing manufacturing steps of the trench MOSFET 200 in FIG. 2 according to the present invention. Referring to FIG. 3A, an N epitaxial layer 201 is initially grown on a heavily doped N+ substrate 202. Next, after an oxide layer 221 is deposited onto top surface of the N epitaxial layer 201, a contact mask (not shown) is applied onto the oxide layer 221 and followed by successive steps of dry oxide etch and silicon etch to form: a plurality of gate trenches 205 in an active area; a wider gate trench 205′ in a gate contact area and a plurality of floating gate trenches 222 in a termination area.

FIG. 3B shows that, a round hole silicon etch is performed to round trench bottoms of all the gate trenches in FIG. 3A and to remove silicon damage during carrying out the silicon etch.

In FIG. 3C, a sacrificial oxide layer (not shown) is formed and then removed from where the silicon etch was performed to eliminate silicon damage which may be introduced during the silicon etch. Then, a gate oxide layer 206 is formed covering inner surface of all the gate trenches 205, 205′ and 222.

In FIG. 3D, a doped poly-silicon material 224 is deposited to fill all the gate trenches (205, 205′ and 222) and cover top surface of the oxide layer 221, and then is removed away from the top surface of the oxide layer 221 by poly CMP (Chemical Mechanical Polishing) or etching back

In FIG. 3E, a step of wet oxide etch is performed to remove the oxide layer 221 as shown in FIG. 3D, exposing top portions of all the doped poly-silicon material above the N epitaxial layer 201, therefore, terrace trenched gate structure is implemented including: a plurality of terrace trenched gates 204 in the gate trenches 205 in the active area; a wider terrace trenched gate 204′ in the wider gate trench 205′ in the gate contact area; and multiple of terrace trenched gates 223 in the floating gate trenches 222 in the termination area.

In FIG. 3F, an ion implantation with p type dopant is carried out and followed by a dopant diffusion step to form a plurality of P body regions 208 which are extending between two adjacent of all the gate trenches (205, 205′ and 222).

In FIG. 3G, another oxide layer serving as a contact interlayer 211 is deposited covering the top surface of the N epitaxial layer 201 while covering outer surface of all the terrace trenched gates (204, 204′ and 223) above the N epitaxial layer 201, at the same time, a source contact hole 225 is formed self-aligned to two adjacent of the terrace trenched gates 204 in the active area because that the contact interlayer 211 is almost uniformly grown along the outer surface of the terrace trenched gates 204, therefore the source contact hole 225 is almost positioned in the middle between two adjacent of the terrace trenched gates 204.

In FIG. 3H, a contact mask 226 is applied onto the contact interlayer 211 with opening windows to define the location of a trenched source-body contact and a trenched gate contact. Wherein the opening window 227 has a greater CD (Critical Dimension) than the source contact hole 225 underneath.

In FIG. 3I, a dry oxide etch is carried out to: form a gate contact hole 228 to expose partial top surface of the wider terrace trenched gate 204′; and to deepen the source contact hole 225 to expose partial top surface of the N-epitaxial layer 201 while enlarging trench CD of a top portion of the source contact hole 225. Next, without applying a source mask, another ion implantation with an n type dopant is carried out to form n+source regions 207 right below a bottom portion of the source contact hole 225 which is self-aligned to two adjacent terrace trenched gates 204, and followed by a source diffusion step to extend the n+ source regions 207 to adjacent channel regions near the gate trenches 205.

In FIG. 3J, a dry silicon etch is carried out to: deepen the gate contact hole 228 into the wider terrace trenched gate 204′; and deepen the source contact hole 225 along sidewalls of the bottom portion, making it penetrate through the n+ source regions 207 and extend into the P body regions 208, wherein the bottom portion of the source contact hole 225 is self-aligned to two adjacent terrace trenched gates 204. Then, a BF2 ion implantation is carried out and followed by RTA (rapid thermal annealing) to form a p+ ohmic body contact region 213 underneath the n+ source regions 207 and surrounding at least bottom of the source contact hole 225.

In FIG. 3K, a layer of Ti/TiN is deposited covering top surface of the contact interlayer 211, along inner surface of the source contact hole 225 and the gate contact hole 228 (as illustrated in FIG. 3J) to serve as a barrier layer (not shown), and followed by another RTA step to form Ti silicide. Next, tungsten material is deposited close to the barrier layer, refilling the source contact hole 225 and the gate contact hole 228 (as illustrated in FIG. 3J). Next, the tungsten material together with the Ti/TiN layer are etched back to be removed away from the top surface of the contact interlayer 211. Then, after a front metal layer of Al alloys or Cu padded by a resistance-reduction layer 229 of Ti is deposited covering the top surface of the contact interlayer 211, a metal mask (not shown) is applied onto the front metal and followed by a metal etch to respectively form a source metal layer 212 and a gate metal layer 214.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A trench MOSFET formed in an epitaxial layer of a first conductivity type and comprising a plurality of terrace trenched gates surrounded by source regions heavily doped with said first conductivity type in an active area encompassed in body regions of a second conductivity type above a drain region, wherein:
said terrace trenched gates comprise poly-silicon material disposed in gate trenches and padded by a gate oxide layer, wherein said poly-silicon material has a top surface higher than a silicon mesa between two adjacent gate trenches;
said source regions formed between trenched source-body contacts and adjacent said gate trenches have a higher doping concentration and a greater junction depth near sidewalls of said trenched source-body contacts than near said adjacent said gate trenches, wherein said trenched source-body contacts are self-aligned to adjacent said terrace trenched gates.

2. The trench MOSFET of claim 1, wherein a top portion of each of said trenched source-body contact has a greater trench width than a bottom portion.

3. The trench MOSFET of claim 1 further comprises a gate contact area including a wider terrace trenched gate disposed in a wider gate trench, wherein said wider terrace trenched gate is connected to a gate metal layer through a trenched gate contact.

4. The trench MOSFET of claim 1 further comprises a termination area including multiple of floating trenched gates which are spaced apart from each other by said body regions having floating voltage, wherein said floating trenched gates also have similar terrace trenched gate structure as said terrace trenched gates in said active area.

5. A method for forming the trench MOSFET of claim 1 comprising:
forming a plurality of terrace trenched gates in a plurality of gate trenches in an epitaxial layer of a first conductivity type, wherein said terrace trenched gates have a top surface higher than said epitaxial layer;
forming a plurality of body regions of a second conductivity type extending between two adjacent of said gate trenches in said epitaxial layer;
depositing a contact interlayer covering outer surface of said terrace trenched gates, forming a source contact hole in the middle of every two adjacent of said terrace trenched gates;
etching said source contact hole to expose partial top surface of said epitaxial layer; carrying out ion implantation of said first conductivity type through said source contact hole to form source regions right below said source contact hole in said epitaxial layer; and
performing diffusion to extend said source regions to adjacent said gate trenches.
